(19) United States
(12) Patent Application Publication
(10) Pub. No.: US 2005/0247990 A1
(43) Pub. Date: Nov. 10, 2005

(54) Image sensor packages and method of assembling the same

(76) Inventor: Ming-Te Cheng, Taoyuan (TW)

Correspondence Address: Jackson Walker L.L.P., Suite 2100, 112 E. Pecan Street, San Antonio, TX, 78205, US

(21) Appl. No.: 10/839,693

(22) Filed: May 5, 2004

(51) Int. Cl. H01L 31/0232; H01L 21/00

(52) U.S. Cl. 257/432; 257/433; 438/65

(57) ABSTRACT

An image sensor package and method of assembling the same utilizes an overlay pattern containing multiple lens mounts and a glass plate to laid over a substrate. The substrate has multiple chip pads formed at predetermined locations for holding sensor ICs. Each lens mount is positioned on the periphery of the chip pad and completely sealed off by a glass plate The stacked layers are then cut vertically to form individual blocks, completely detached to form image sensor packages.

### BACKGROUND OF THE INVENTION

1. Field of the Invention

The present invention is related to image sensor packages and a method of assembling the image sensors, and more particularly to a technique of assembling a two dimensional array of CMOS image sensors.

2. Description of Related Art

CMOS image sensors are not only used in digital cameras as the image capturing devices, but these image sensors are also incorporated in many mobile phones to create additional functions.

According to the conventional method, an image sensor, as shown in FIG. 6, is usually assembled following the procedures to be described below.

A substrate die with multiple sensor ICs is first prepared, where the sensor ICs are placed on top of bonding pads. The sensor ICs (102) are then connected to the lead wires on the periphery of the sensor ICs (102) (not shown in the diagram) through a wire bonding process. The substrate die is then cut into individual blocks (101) of uniform size, each having a sensor IC (102) placed over a bonding pad that is formed on the substrate (101). A quadrangular lens mount (103) is then placed around the sensor IC (102) and secured over the substrate (101) by thermal compression. Thereafter, a glass plate (107) is glued on top of the lens mount (103), and finally, a lens assembly (104) is mounted over the glass plate (107).

The main drawback in the above method is the large amount of manual processes involved from placing of the lens mounts (103) over individual substrates (101), the glass plates (107) over the lens mounts (103), to mounting of the lens assembly (104) over individual substrates (101). In the manual assembling processes, lateral shifting is inevitably introduced through the hands of assembly line workers. Once a shift is made, the effect will be accumulated through downstream processes, causing the image sensor device to make an incorrect adjustment between the prism (105) and the sensor IC (102). A focusing error will result in image loss and distortion problems.

Also, to attach the glass plates (107) onto the lens mounts (103), viscose glue is applied on the top surface of the lens mount (103). If excess amount of glue is applied on the top surface of the lens mount (103), the glass plate (107) will be suspended by the glue arbitrarily, so that the glass plate (107) cannot be laid directly on top of the lens mount (103). In such case, the lens assembly (104) cannot be mounted and aligned on top of the lens mount (103) and the substrate (101). As a result, the direction and position of all sensors in the array are not lined up uniformly. Conversely, if an inadequate amount glue is used, the components cannot be secured, so the image sensors become unreliable in operation.

Another conventional image sensor is shown in FIG. 7. Like the previous example, the sensor die having multiple sensor ICs is cut into individual blocks (101) of equal size, each having a sensor IC (102) placed over a bonding pad and the chip pad is formed on the substrate (101). The sensor ICs (102) are connected to the leads on the periphery of the substrates (101) (not shown in the diagram). Thereafter, quadrangular lens mounts (103) are placed over individual substrates (101), positioned on the periphery of the sensor ICs (102).

When the image sensor is put to use, a lens assembly (104) needs to be installed over the sensor IC (102). This lens assembly (104) has a hollow passage in the center with threaded inner surface, in which a prism (107) is installed, where the prism (107) is formed by a combination of reflection mirrors (105). The top of the lens assembly (104) has an opening (106) that extends downward through the central passage to the sensor IC (102) at the bottom. The lens assembly (104) also has multiple cuts (1041) on the outer wall near the bottom section and the lens mount (103) has multiple locks (1031), that allow the lens assembly (104) to latch onto the lens mount (103) through the action of the locks (1031) and corresponding cuts (1041).

However, the above-mentioned sensor package (102) does not have a glass plate to protect the sensor IC (102) from dust contamination. If a foreign object drops on top of the sensor IC (102), the automatic adjustment of the lens assembly (104) and the prism (107) will not be able to attain the true focusing point, hence distortion will appear over the captured images.

From the two examples mentioned above, it can be understood that the manual assembling processes will consume considerable amount of time for attaching the lens mounts (103) onto cut substrates (101), and then the glass plates (107) of the same size over individual lens mounts (103), not to mention the lateral shifting in the assembling processes that will cause distortion problems.

### SUMMARY OF THE INVENTION

The main object of the present invention is to provide a method of assembling image sensor package that is capable of reducing the assembling time considerably as well as increasing the production yield.

The second object of the invention is to provide an image sensor package that is assembled according to the assembling method described above.

To this end, the instrumentalities of the present invention include:
preparing a substrate die having multiple chip pads, formed at predetermined positions; multiple die locating holes in the central area and on the periphery; multiple locating holes around the chip pad; and multiple locating holes for lens assembly on the outside of the pad locating holes;
attaching an overlay pattern containing multiple quadrangular lens mounts onto the substrate die, where the lens mounts are supported by interlinking poles; and the overlay pattern has pillars on the bottom surface of the poles, corresponding to the positions of the die locating holes, used for accurately positioning the overlay pattern on top of the substrate die to allow individual lens mounts to be placed on the periphery of sensor ICs; and the top and bottom surfaces of each lens mount has grooves used for holding viscose glue; and the bottom surface of each lens mount also has multiple pillars that correspond to the positions of locating holes around chip pad to allow each lens mount to be positioned on the periphery of a chip pad;
placing sensor ICs over corresponding chip pads, and then wire bonding the chip pads holding the sensor ICs to make electrical connections to the lead wires on the substrate;
binding a glass plate over the overlay pattern, in a manner that the glass plate is enough to cover all lens mounts; and
cutting vertically through the stacked layers of the glass plate, the overlay pattern, and the sensor die along the separation lines to separate into individual blocks of equal shape and size, which are completely detached to form individual image sensor packages.

The above cutting process is further divided into two stages:
a first stage is to cut through the glass plate and the poles of the overlay pattern, so that the interlinked lens mounts are divided into multiple quadrangular blocks of uniform shape and size; and
the second stage is to cut through the sensor die and reserve the locating holes for mounting the lens assembly on individual substrates, so the detached blocks are complete to form individual image sensor packages.

According to the present invention, a pre-fabricated overlay pattern is provided, which contains multiple lens mounts formed at predetermined locations and supported by interlinking poles. The overlay pattern is to be attached over the substrate die in such a way that each lens mount is positioned on the periphery of a chip pad, and then a glass plate is laid over the overlay pattern. Thereafter, the stacked layers containing the glass plate, the overlay pattern, and the sensor die are cut vertically, to be separated into blocks of equal size and shape by a mechanical means, which are complete to form individual image sensor packages. Through the above-mentioned assembling processes, the production efficiency can be considerably increased and the production yield will also be improved.

According to the present invention, the top and bottom surfaces of the lens mount are designed with grooves, which are used to hold excessive viscose glue during the gluing and thermal compression. In normal situations, the glue will be displaced as the glass plate and the substrate die are pressed during thermal compression process, and excess amount of glue will flow into the grooves, allowing the glass plate and the lens mounts to be laid flat on the stacked surfaces. As a result, the direction and the position of image sensors in the array can be lined up uniformly.

Other objectives, advantages and novel features of the invention will become more apparent from the following detailed description when taken in conjunction with the accompanying drawings.

### BRIEF DESCRIPTION OF THE DRAWINGS

FIG. 1 is a conceptual diagram showing the assembling processes for the image sensor packages according to the present invention;

FIG. 2 is a perspective view of the external form of the lens mount;

FIG. 3 is a cross-sectional view of two adjacent sensor ICs on a substrate with the lens mounts and the glass plates attached;

FIG. 4 is a cross-sectional view of an image sensor package;

FIG. 5 is a cross-sectional view of an image sensor package with a lens mounted;

FIG. 6 is a cross-sectional view of a conventional image sensor with the lens; and

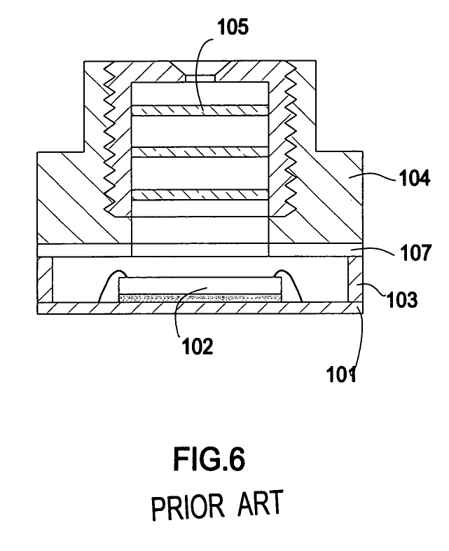

FIG. 7 is a cross-sectional view of another conventional image sensor with the lens.

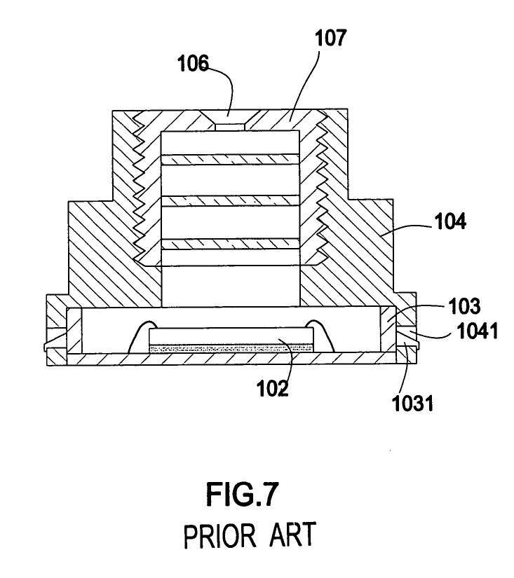

### DETAILED DESCRIPTION OF THE PREFERRED EMBODIMENT

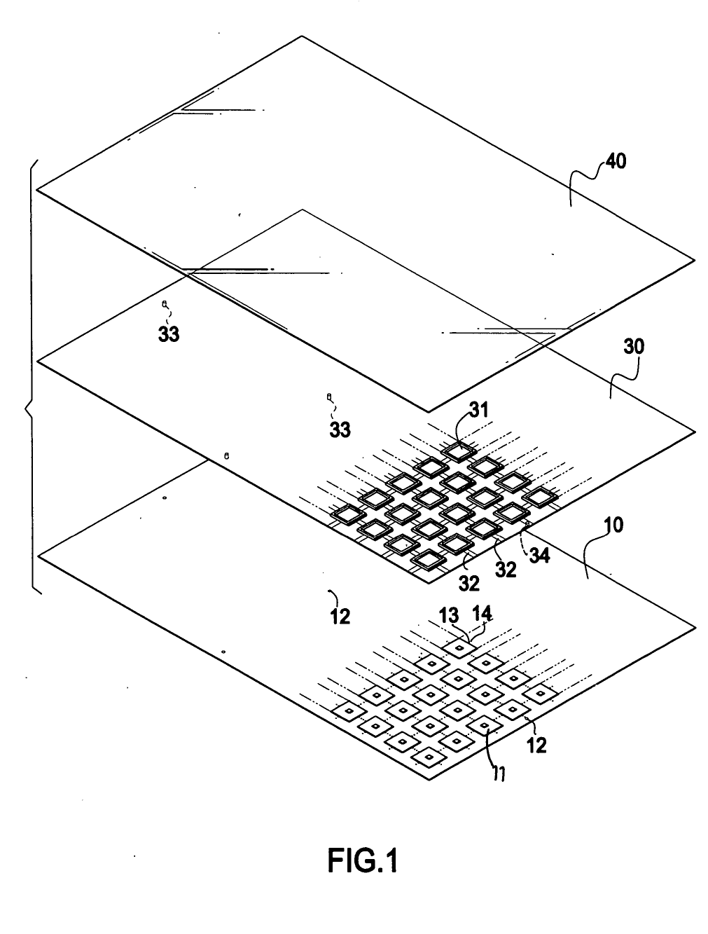

The present invention is illustrated through a first preferred embodiment, shown in FIGS. 1-4, which is assembled according to the following procedures.

In the step of preparing a substrate (10), the substrate (10) has multiple chip pads (11) formed at predetermined locations on the surface of the substrate (10). Multiple substrate locating holes (12) are defined in the central area and on the periphery of the substrate (10). Multiple chip locating holes (13) and lens assembling locating holes (14) are defined on the periphery of each chip pad (11).

In the step of attaching an overlay pattern (30), multiple quadrangular lens mounts (31) are preformed by a molding machine and interconnected to each other by interlinking ribs (32). The overlay pattern (30) is mounted over the substrate (10), wherein the bottom surface of the overlay pattern (30) has pillars (34) to correspond to the substrate locating holes (12) on the substrate(10).

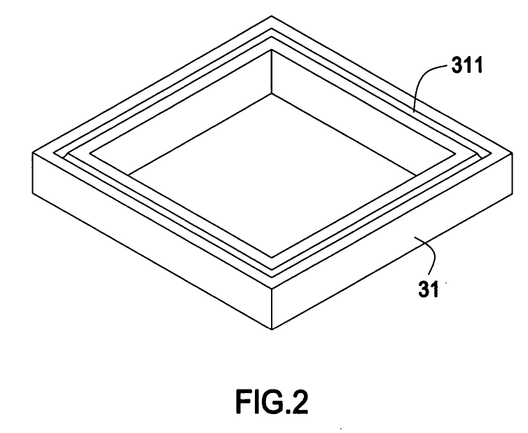

With reference to FIG. 2, each lens mount (31) has grooves (311)(312) respectively defined on the top and bottom surfaces for holding overflow glue. In the present example, ring-shaped grooves are used, but it is possible to use other shapes. For example, the grooves on top and bottom of the lens mount (31) can be two parallel lines. Each individual lens mount (31) has stubs (33) formed on the bottom surface of the bottom groove (312) to correspond to the chip locating holes (13) around the chip pad (11). Therefore the overlay pattern (30) can be positioned in such a way that each lens mount (31) is positioned on the periphery of a corresponding chip pad (11).

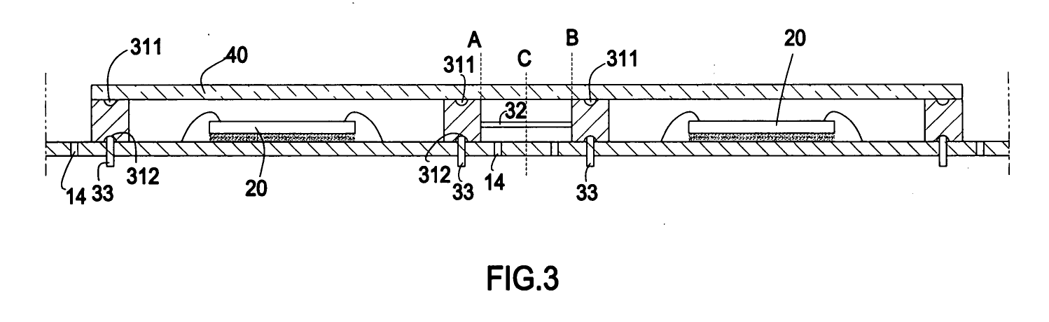

After glue is applied on the bottom surface of the overlay pattern (30), the pillars (34) of the overlay pattern (30) are to be fitted into corresponding die locating holes (12). At this time the stubs (33) on lens mounts (31) can also be inserted into the chip locating holes (13) around chip pad (11), such that the overlay pattern (30) can be secured over the substrate (10) as shown in FIG. 3. Any excess amount of glue will be displaced into the grooves (312) as the overlay pattern (30) is pressed against the substrate (10). Therefore the bottom surface of the overlay pattern (30) can be laid flat over the substrate (10).

In the step of attaching sensor ICs (20) over corresponding chip pads (11), wire bonding process is also applied to connected the ICs (20) to plural lead wires (not shown) around the periphery of the chip pad (11) thus establishing electrical connections.

In the step of binding a glass plate (40) over the overlay pattern (30), a glass plate (40) is large enough to cover all lens mounts (31). In this step, viscose glue is applied on the top surface of the overlay pattern (30), any excess amount of glue will be displaced into the top grooves (311) as the glass plate (40) is pressed against the overlay pattern (30), so that the glass plate (40) can be laid flat over the overlay pattern (30) as shown by FIG. 3.

In the step of cutting, after properly binding the glass plate (40) and the overlay pattern (30) and allowing for sufficient curing time, the stacked layers of the glass plate (40), the overlay pattern (30) and the sensor (10) are cut to be separated into individual blocks of equal size and shape, which are then completely detached to form individual image sensor packages.

The cutting process is divided into two stages, wherein the first stage is to cut vertically through the stacked layer of the glass plate (40) and the ribs (32) of the overlay pattern (30) (along dotted lines A, B in FIG. 3) to form individual blocks of uniform size and shape.

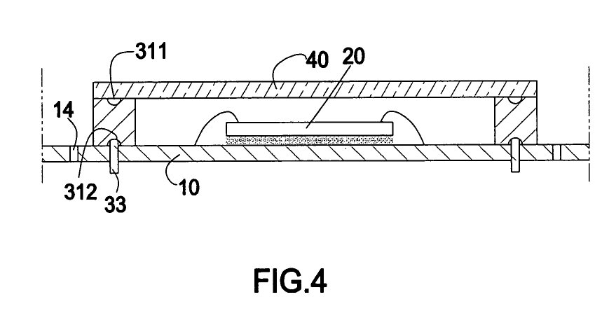

Then the second stage is to cut through the substrate (10) (along dotted line C shown in FIG. 3) and to reserve the lens assembling locating holes (14) for mounting the lens assembly. The detached blocks form individual image sensor packages as shown in FIG. 4.

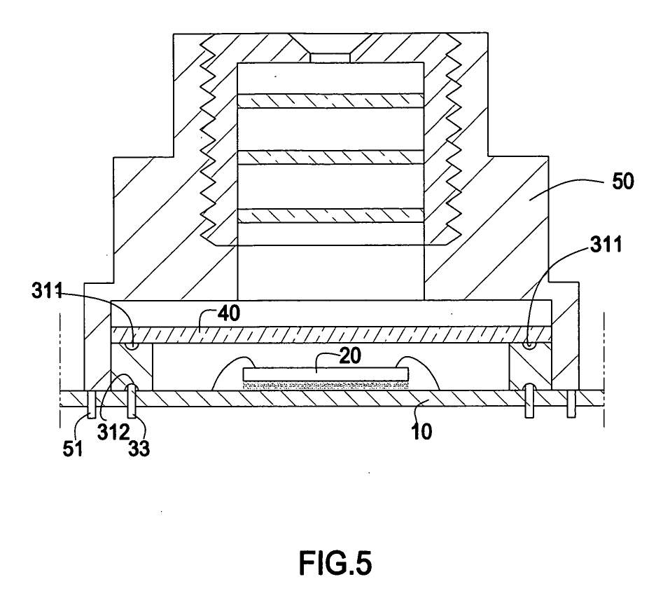

Actually, the image sensor package is used in conjunction with the lens assembly (50), as shown in FIG. 5. There are multiple locating holes for lens assemblies (14) surrounding each chip pad (11) on the sensor die (10). During the second-stage cutting, the substrate (10) is cut through vertically to be separated into individual sensor substrates and the locating holes (14) for lens assemblies are reserved on individual substrates (10). The lens assembly (50) has multiple pillars (51) on the bottom surface corresponding to the locating holes for lens assemblies (14) for securing the lens assembly (50) over the sensor die (10).

According to the present assembling method, to form the image sensor array, the overlay pattern (30) and the glass plate (40) are laid sequentially over the sensor die (10) and then the stacked layers of the glass plate (40), the overlay pattern (30) and the substrate (10) are cut vertically by mechanical means to be separated into multiple blocks, where each block is completely detached to form an image sensor package.

The assembling process is notably different from the conventional way of assembling, in which the sensor die is first cut into individual blocks, and then the lens mounts and the glass plates are individually laid by manual processes. Hence, the present method enables improved production efficiency, and the production yield will also be enhanced.

It is to be understood, however, that even though numerous characteristics and advantages of the present invention have been set forth in the foregoing description, together with details of the structure and function of the invention, the disclosure is illustrative only, and changes may be made in detail, especially in matters of shape, size, and arrangement of parts within the principles of the invention to the full extent indicated by the broad general meaning of the terms in which the appended claims are expressed.

1. A method of assembling image sensor packages, comprising the steps of:
preparing a substrate (10) having multiple chip pads (11) that are formed at predetermined locations on the substrate (10), wherein multiple substrate locating holes (12) are defined on the substrate die (10), multiple chip locating holes (13) are defined around each chip pad (11), and multiple lens assembling locating holes (14) are defined around each chip pads (11);
mounting an overlay pattern (30) over the substrate (10), wherein the overlay pattern (30) is formed by multiple lens mounts (31) that are connected each other by ribs (33), wherein each lens mount (31) is to be placed along the periphery of a corresponding chip pad (11), wherein a top and a bottom surfaces of each lens mount (31) has at least one groove (311, 312);
placing a sensor IC (20) over each chip pad (11) and wire bonding to connect the sensor IC (11) to plural lead wires formed around the chip pad (11);
mounting a glass plate (40) over overlay pattern (30) to cover all lens mounts (31); and
cutting through the stacked layers of the glass plate (40), the overlay pattern (30) and the sensor die (10) to form multiple individual image sensor packages.

2. The method of assembling image sensor packages according to claim 1, wherein the cutting step comprises two stages:
a first stage is to cut through the stacked glass plate (40) and the ribs (33) of the overlay pattern (30) to be separated into individual blocks of equal size and shape, each of which contains a lens mount (31) with a piece of glass plate (40) of equal size attached thereon;
a second stage is to cut through the substrate (10) and to reserve the lens assembling locating holes (14) for mounting the lens assembly on individual substrates (10), so that the detached blocks are complete to form individual image sensor packages.

3. The method of assembling the image sensor packages according to claim 1, wherein the glass plate (40) is attached onto the overlay pattern (30) through a binding process with viscose glue applied on the top surface of the overlay pattern (30) to bind the glass plate (40) and the overlay pattern (30) together.

4. The method of assembling the image sensor packages according to claim 2, wherein the glass plate (40) is attached onto the overlay pattern (30) through a binding process with viscose glue applied on the top surface of the overlay pattern (30) to bind the glass plate (40) and the overlay pattern (30) together.

5. The method of assembling the image sensor packages according to claim 1, wherein the overlay pattern (30) is attached onto the substrate (10) through a binding process with viscose glue applied on the bottom surface of the overlay pattern (30) to bind the overlay pattern (30) and the substrate die (10).

6. The method of assembling the image sensor packages according to claim 2, wherein the overlay pattern (30) is attached onto the substrate (10) through a binding process with viscose glue applied on the bottom surface of the overlay pattern (30) to bind the overlay pattern (30) and the substrate die (10).

7. The method of assembling image sensor packages according to claim 1, wherein the substrate locating holes (12) are defined in the central area and on the periphery of the substrate die (10) to correspond to the ribs (34) thus allowing the overlay pattern (30) to be secured over the substrate die (10).

8. The method of assembling image sensor packages according to claim 1, the multiple chip locating holes (13) are defined at predetermined locations on the substrate (10) to correspond to the positions of pillars (33) formed underneath the lens mounts (31) thus allowing the lens mounts (31) to be secured over the substrate die (10).

9. The method of assembling the image sensor packages according to claim 1, wherein the multiple locating holes (14) are for lens assembly (14) defined around the chip pad (11) and near the chip locating holes (13) to correspond to pillars (51) formed underneath the lens assembly (50), allowing the lens assembly (50) to be mounted over the glass plate (40) and the substrate die (10).

10. An image sensor package, comprising:
a substrate block (10) over which a chip pad (11) is formed for holding a sensor IC (20);
a lens mount (31) placed along periphery of the chip pad (11) and defined with grooves (311, 312) on a top surface and a bottom surface for holding overflow glue; and
a glass plate (40), of the same size as the lens mount (31), attached over the lens mount (31) for sealing off the sensor IC (20) in the hollow space in the center of the lens mount (31).

11. The image sensor package according to claim 10, wherein multiple locating holes (14) are reserved on the substrate (10) along the periphery of lens mount (31) for attaching a lens assembly (50) over the glass plate (40) and the substrate (10).
